(19) United States
(12) Patent Application Publication
(10) Pub. No.: US 2009/0029070 A1
(43) Pub. Date: Jan. 29, 2009

(54) METHOD OF PRODUCING NANOWIRES IN AMBIENT CONDITIONS AND NANOWIRES THUS PRODUCED

(75) Inventors: Felix Quintero Martinez, Vigo(Pontevdra) (ES); Juan Maria Pou Saracho, Vigo(Pontevedra) (ES); Fernardo Lusquinos Rodriguez, Vigo(Pontevedra) (ES); Mohamed Boutinguiza Larosi, Vigo(Pontevedra) (ES); Ramon Francisco Soto Costas, Vigo(Pontevedra) (ES); Mariano Jesus Perez-Martinez Y Perez-Amor, Vigo(Pontevedra) (ES)

Correspondence Address: INTELLECTUAL PROPERTY / TECHNOLOGY LAW, PO BOX 14329, RESEARCH TRIANGLE PARK, NC, 27709, US

(73) Assignee: Universidad de Vigo

(21) Appl. No.: 11/721,731

(22) PCT Filed: Dec. 17, 2004
(86) PCT No.: PCT/ES04/00566

§ 371 Date: Jun. 14, 2007

(51) Int. Cl. C23C 14/28

(52) U.S. Cl. 427/596

(57) ABSTRACT

The invention relates to a method whereby it is possible to obtain nanowires by means of applying a laser radiation and simultaneously injecting a supersonic gas stream on the precursor material in atmospheric conditions and at room temperature. This method involves a considerable improvement compared to conventional methods because it can be carried out on commercial samples without any prior preparation, a very precise control of the process and environmental conditions not being necessary, which significantly decreases the process time and the economic cost thereof. The method object of the present invention also allows synthesizing nanowires in very reduced processing times.

### OBJECT OF THE INVENTION

The present invention is comprised within the field of nanostructures or nanometric scale materials.

It is possible to obtain nanowires by applying a laser radiation in atmospheric conditions and at room temperature by means of the method object of the present invention.

### BACKGROUND OF THE INVENTION

The field of the nanostructure science and technology which arose in the 1980 decade involved a strong boost for developing new materials and products, opening up new research lines and technological breakthroughs. The essence of nanotechnology is the ability to produce nanostructures in nanometric scale with new molecular arrangements. The behavior of the materials organized in nanometric structures has features that are well distinguished from the macroscopic material. For this reason, the development of new nanostructure is very interesting to explore the use of materials and systems with new and improved physical, chemical and biological properties and the discovery of new phenomena and processes in the materials science field.

Since the publication in 1986 of the synthesis of nanometric particle chains in the form of wires with a diameter of only several nanometers (E. E. D. Chidsey and R. W. Murria, Science, vol. 231, page. 25, 1986) and the formation of nanometric scale carbon tubes in 1991 (S. Iijima, Nature, vol. 354, page 56, 1991), the enormous potential involved with these nanostructures with new properties for developing new nanoelectronic, computer, energy technology devices etc. has been discovered.

Multiple techniques for the synthesis and production of nanowires made of diverse materials have been developed with the support of new nanotechnology horizons, the interest has fundamentally been focused on producing nanowires made of conductor materials, semiconductor materials and semiconductor oxides. The methods used have been classified based on the physical condition of the precursor material (liquid, solid or gas) and on the mechanism promoting the material deposition and the formation of nanostructures, either by means of a chemical reaction or physical transformations of the material. Therefore, the followings methods are the most used methods in the synthesis of nanowires: the reactions for filling mesoporous molds or carbon nanotubes, the synthesis by means of the reaction of liquid solutions or polymer growth are emphasized among the methods based on the formation of chemical reactions; whereas the thermal evaporation of solid substrates in controlled atmosphere chambers, hot-filament-assisted gaseous deposition, electrodeposition and laser ablation in vacuum chambers are emphasized among the methods promoting physical transformations. Laser ablation is perhaps the method which provides the most promising results out of the indicated methods given that it allows obtaining large amounts of highly pure nanowires without a support substrate.

### DESCRIPTION OF THE INVENTION

The present invention sets forth a laser application for producing nanowires. This method is based on the same physical principles as the laser ablation method but it incorporates a series of substantial differences involving advantages with respect to the production process and to the end product. As regards the production process, the method object of the present patent has the advantage of being carried out in atmospheric conditions and at room temperature, therefore the use of vacuum chambers, controlled atmosphere reaction chambers, systems for measuring and controlling the process temperature or systems for measuring and controlling the process pressure, required in the laser ablation method, are not required.

Another advantage of the invention object of the present patent is the simplicity of both the devices and the processes conducted, because the present process is carried out in atmospheric conditions, at room temperature and on a solid-state sample.

In addition, the method object of the present invention can be carried out on commercial samples without any prior preparation, a very precise control of the process and environmental conditions not being necessary, which significantly reduces the process time and the economic cost thereof.

The method object of the present invention can be implemented in continuous production systems because it does not require confining the precursor material in a processing chamber with controlled conditions or in a vacuum chamber, therefore the size of the samples is not limited by the capacity of said chamber. On the other hand, the precursor material of the nanowires does not require the complex preparation which is necessary in the previously indicated methods.

As regards the product obtained, the method object of the present invention allows synthesizing larger amounts of nanowires in very reduced processing times: it is therefore possible to synthesize grams of nanowires in minutes compared to the several tens of hours required in some of the current methods.

The product is obtained free of substrate and in purity and morphological conditions that are equivalent to those provided by the laser ablation method in a vacuum chamber. The nanowires produced have lengths from tens of microns and diameters from a few tens of nanometers with slightly curved shapes. The present method allows the application to different substrates for producing nanowires made of different amorphous materials.

### DESCRIPTION OF THE FIGURES

To complement the description which is being made and with the aim of aiding to better understand the features of the invention according to a practical embodiment thereof, a single FIGURE is attached as an integral part of said description, in which a schematic and side elevational view of a laser beam impinging on a precursor material causing the generation of nanowires by the method corresponding to the present invention has been shown.

### PREFERRED EMBODIMENT OF THE INVENTION

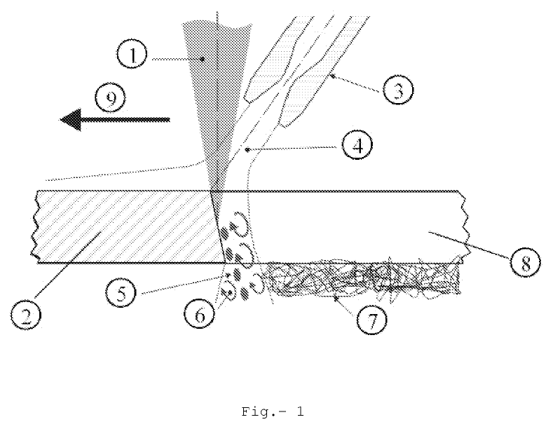

The method for producing nanowires in environmental conditions object of the present invention is carried out in a suitable system, an example of which is shown in FIG. 1, This method basically consists of the following: the precursor material (2) from which the nanowires will be formed, is located on a suitable support for its dimensions in a moving system. Said system can consist of any type of robot, of any type of coordinate table, or of a combination of both systems. This system will be connected to a system for automatically controlling the position of the part, which is not shown in the FIGURE because it is a commonly used part in industrial equipment. The laser beam (1) is led towards the precursor material (2) by means of a suitable beam guiding system (which can be either a mirror system or optical fiber, according to the type of laser source used). The joint action of the laser beam (1) and a gas stream (4) working in supersonic conditions is needed to produce nanowires. This gas stream (4) is supplied to the interaction area between the laser beam (1) and the precursor material (2) by means of a supersonic nozzle (3). The assisting gas stream is directed to the cutting area forming an inclination angle between 25 and 50° with respect to the axis of the laser beam (5). Said gas stream (4) impinges on the interaction area of the laser beam (1) and the precursor material (2), causing a turbulent flow with the formation of eddies (6), such that the small molten material particles (5) which are removed from the precursor material (2) are trapped in said eddies (6). This fact makes the molten material particles (5) make a close contact with the vapor coming from the sublimation of the precursor material (2), such that nanowires (7) are generated.

In order to obtain a large amount of nanowires (7), there is a movement (9) of the laser beam (1) with respect to the precursor material (2), whereby the nanowires (7) are located under the already irradiated precursor material (8).

The laser radiation can come from laser equipment of any wavelength such as, for example a CO₂, CO, N₂, Nd:YAG, Er:YAG, Nd:glass, Ruby, HeNe, HeCd, HeHg, Cu, I, Ar, Kr laser, a laser diode, a chemical laser, an excimer laser, an alexandrite laser, am emerald laser or a dye laser. In any case, the best results have been obtained using CO₂ or Nd:YAG lasers. The power necessary for this type of lasers can be between 50 and 3000 W, the best results having been obtained when working with a power between 300 and 1000 W.

The laser beam (1) is focused by means of a lens (not shown in the FIGURE). This lens will be carried out in such a manner and in a material such that it allows transmitting the energy of the laser beam (1). This lens will have a focal length between 80 and 300 mm.

The assisting gas injected through the supersonic nozzle can be an inert gas (Ar, He, Ne, N₂) or an oxidant gas (O₂, CO₂, compressed air).

The precursor material can be a ceramic, metal, polymer, hybrid material part, etc. . . .

### EXAMPLE

The following example is a practical example of the application of the method for producing nanowires in environmental conditions: Si—Al-0 nanowires with diameters between 30 and 100 nanometers and lengths of several hundreds of micrometers were obtained at a rate of 20 mm³ per second. To that end, a Nd:YAG laser (λ=1.06 μm) was used, working in pulsed mode at a frequency of 120 Hz, with a pulse width of 1 ms, with argon gas at a pressure of 8×10⁵ Pa and with a power of 430 W. A mullite matrix composite with alumina grains was used as the precursor material. The relative speed of movement between the laser beam and the precursor material was 1 mm/s.

1. A method for producing nanowires in an ambient environment comprising:
a) disposing precursor material for the nanowires on a support in a moving system connected to equipment for controlling the position of the precursor material,
b) irradiating the precursor material with a laser beam and simultaneously injecting a supersonic gas stream in an interaction area between the laser beam and the precursor material, simultaneously generating vapor and molten particles from the precursor material and from eddies caused by turbulence of the supersonic gas stream in interaction with the precursor material irradiated by the laser beam, and
c) effecting relative movement between the precursor material and the laser beam.

2. A method according to claim 1, wherein the gas stream is directed to a cutting area and forms an inclination angle between 25° and 50° with respect to an axis of the laser.

3. A method according to claim 1, wherein the power supplied by the laser beam is in a range from 50 to 3000 W.

4. A method according to claim 3, wherein the power supplied by the laser beam is in a range from 300 to 1000 W.

5. A method according to claim 1, wherein the moving system connected to the equipment for controlling the position of the precursor material includes a robot, a coordinate table, or a combination thereof.

6. Nanowires produced by the method according to claim 1.

7. A method according to claim 2, wherein the power supplied by the laser beam is in a range of from 50 to 3000 W.

8. A method according to claim 2, wherein the moving system connected to the equipment for controlling the position of the precursor material includes a robot, a coordinate table, or a combination thereof.

9. A method according to claim 3, wherein the moving system connected to the equipment for controlling the position of the precursor material includes a robot, a coordinate table, or a combination thereof.

10. A method according to claim 4, wherein the moving system connected to the equipment for controlling the position of the precursor material includes a robot, a coordinate table, or a combination thereof.
